(19) United States
(12) Patent Application Publication
(10) Pub. No.: US 2025/0141471 A1
(43) Pub. Date: May 1, 2025

(54) FAIR-DENSITY PARITY-CHECK CODING AND DECODING

(71) Applicant: Northeastern University, Boston, MA (US)

(72) Inventor: Hessam Mahdavifar, Waltham, MA (US)

(21) Appl. No.: 18/927,527

(22) Filed: Oct. 25, 2024

Related U.S. Application Data
(60) Provisional application No. 63/545,623, filed on Oct. 25, 2023.

(51) Int. Cl. H03M 13/11

(52) U.S. Cl. CPC H03M 13/116; H03M 13/1111; H03M 13/1188

(57) ABSTRACT

Error-corrected communication is provided. A base matrix is constructed. The base matrix comprises a plurality of columns. A plurality of permutations is applied to the base matrix to obtain a plurality of permuted matrices. A parity-check matrix is generated by concatenating the plurality of permuted matrices. A plurality of codewords is generated based on the parity-check matrix. A message is encoded according to the plurality of codewords. The encoded message is transmitted via a noisy channel.

### CROSS-REFERENCE TO RELATED APPLICATIONS

This application claims priority from U.S. Provisional Application No. 63/545,623, titled “FAIR-DENSITY PARITY-CHECK CODING AND DECODING” filed on Oct. 25, 2023, the entire contents of which are hereby incorporated by reference.

### BACKGROUND

Embodiments of the present disclosure relate to codes defined over sparse structures, and more specifically, to fair-density parity check codes targeting high-rate applications.

### BRIEF SUMMARY

According to embodiments of the present disclosure, methods and systems of and computer program products for error-corrected communication are provided. In some embodiments, a base matrix is constructed. The base matrix comprises a plurality of columns. A plurality of permutations is applied to the base matrix to obtain a plurality of permuted matrices. A parity-check matrix is generated by concatenating the plurality of permuted matrices. A plurality of codewords is generated based on the parity-check matrix. A message is encoded according to the plurality of codewords. The encoded message is transmitted via a noisy channel.

In some embodiments, a system is provided. The system comprises a computing node. The computing node comprises a computer readable storage medium having program instructions embodied therewith. The program instructions are executable by a processor of the computing node to cause the processor to perform a method. The method comprises the following steps: A base matrix is constructed. The base matrix comprises a plurality of columns. A plurality of permutations is applied to the base matrix to obtain a plurality of permuted matrices. A parity-check matrix is generated by concatenating the plurality of permuted matrices. A plurality of codewords is generated based on the parity-check matrix. A message is encoded according to the plurality of codewords. The encoded message is transmitted via a noisy channel.

In some embodiments, a computer program product for parity-check coding and decoding is provided. The computer program product comprises a computer readable storage medium having program instructions embodied therewith. The program instructions are executable by a processor to cause the processor to perform a method. The method comprises the following steps: A base matrix is constructed. The base matrix comprises a plurality of columns. A plurality of permutations is applied to the base matrix to obtain a plurality of permuted matrices. A parity-check matrix is generated by concatenating the plurality of permuted matrices. A plurality of codewords is generated based on the parity-check matrix. A message is encoded according to the plurality of codewords. The encoded message is transmitted via a noisy channel.

### BRIEF DESCRIPTION OF THE DRAWINGS

The accompanying drawings, which are incorporated into and constitute a part of this specification, illustrate various exemplary embodiments and together with the description, serve to explain the principles of the disclosed embodiments.

FIG. 1 is a flowchart illustrating a method according to embodiments of the present disclosure.

FIG. 2 is a graph illustrating a performance comparison over BECs (n=256, k=195). Specifically, FDPC codes according to embodiments of the present disclosure are compared against fundamental bounds as well as polar-CRC with SCL decoder.

FIG. 3 is a graph illustrating a performance comparison over B-AWGN (n=1024, rate=0.878). Specifically, FDPC codes according to embodiments of the present disclosure are compared against 5G-LDPC, polar CRC and BCH codes.

FIG. 4 is a graph illustrating a performance comparison over B-AWGN (n=16384, rate=0.97) according to embodiments of the present disclosure.

FIG. 5 is a schematic illustrating an example of a computing node according to embodiments of the present disclosure.

### DETAILED DESCRIPTION

The present disclosure provides fair-density parity-check (FDPC) codes for targeting high-rate applications. In particular, in some embodiments of the present disclosure, a base parity-check matrix H_{b} can be used as a starting point. The base parity-check matrix H_{b} can have dimension 2\sqrt{n}×n, where n is the code block length. The number of ones in each row and column of H_{b} can be equal to \sqrt{n} and 2, respectively. In some embodiments, a deterministic combinatorial method for picking the base matrix H_{b}, assuming n=4t² for some integer t≥2, is provided. In some embodiments, this method can be extended by obtaining permuted versions of H_{b} (e.g., via random permutations of its columns) and stacking them on top of each other, leading to codes of dimension k≥n−2s\sqrt{n}+s, for some s≥2, referred to as order-s FDPC codes.

In some embodiments, methods are provided to explicitly characterize and bound the weight distribution of the new codes and utilize them to derive union-type approximate upper bounds on their error probability under Maximum Likelihood (ML) decoding. In some embodiments, for the binary erasure channel (BEC), it is demonstrated that the approximate ML bound of FDPC codes closely follows the random coding upper bound (RCU) for a wide range of channel parameters. In some embodiments, FDPC codes, under the low-complexity min-sum decoder, improve upon 5G-LDPC codes for transmission over the binary-input additive white Gaussian noise (B-AWGN) channel by almost 0.5 dB (for n=1024, and rate=0.878). In some embodiments, a new decoder is provided as a combination of a weighted min-sum message-passing (MP) decoding algorithm together with a new progressive list (PL) decoding component, referred to as the MP-PL decoder, to decode FDPC codes and to further boost the performance of the codes.

Simulation results are shown for various high-rate FDPC codes in moderate-to-large block length regimes according to some embodiments of the present disclosure. It is numerically demonstrated that these codes beat alternative codes for various channels and a wide range of parameters, with the significantly lower-complexity and lower-latency MP-PL decoder.

This disclosure enables new code constructions and decoding algorithms in high-rate regimes suitable for ultra-high throughput (e.g., high-frequency/optical) applications. Accordingly, the present disclosure is applicable in the context of wireless networks such as cellular networks and similar high throughput environments.

The present disclosure describes a new class of error-correcting codes, referred to as fair-density parity-check (FDPC) codes. The codes target high-rate applications including high-speed wireless and wireline links. In some embodiments, the code construction can be via directly designing the parity-check matrix. In some embodiments, the design can be based on a base matrix with a combinatorial design. In some embodiments, the number and the indices of ones in each row and column of the base matrix can be designed in a certain novel way. In some embodiments, this base matrix can be extended by obtaining permuted versions of the base matrix and stacking them on top of each other, leading to codes of general dimensions. In some embodiments, a combination of a weighted min-sum message-passing (MP) decoding algorithm together with a new progressive list (PL) decoding component, referred to as the MP-PL decoder, can be used to decode FDPC codes. Simulation results confirm the superiority of high-rate FDPC codes in moderate-to-large code block length regimes, compared to other state-of-the-art codes, for various channels and a wide range of parameters, with the significantly lower-complexity and lower-latency MP-PL decoder.

Reference will now be made in detail to the exemplary embodiments of the present disclosure, examples of which are illustrated in the accompanying drawings. Wherever possible, the same reference numbers will be used throughout the drawings to refer to the same or like parts.

The systems, devices, and methods disclosed herein are described in detail by way of examples and with reference to the figures. The examples discussed herein are examples only and are provided to assist in the explanation of the apparatuses, devices, systems, and methods described herein. None of the features or components shown in the drawings or discussed below should be taken as mandatory for any specific implementation of any of these devices, systems, or methods unless specifically designated as mandatory.

Also, for any methods described, regardless of whether the method is described in conjunction with a flow diagram, it should be understood that unless otherwise specified or required by context, any explicit or implicit ordering of steps performed in the execution of a method does not imply that those steps must be performed in the order presented but instead may be performed in a different order or in parallel.

As used herein, the term “exemplary” is used in the sense of “example,” rather than “ideal.” Moreover, the terms “a” and “an” herein do not denote a limitation of quantity, but rather denote the presence of one or more of the referenced items.

In various embodiments of the present disclosure, a new family of codes is provided, named fair-density parity-check (FDPC) codes, targeting high-rate applications together with a parallelizable and low-complexity variation of message-passing (MP) decoder boosted with a newly proposed progressives list (PL) decoder component, referred to as the MP-PL decoder.

Base code construction: Let n=4t², for some integer t≥2. The parameter n is the code block length. Then, in some embodiments, the base parity-check matrix H_{b} can be constructed as follows: The matrix H_{b} consists of all binary column-vectors of length 4t and Hamming weight two with the indices of the two non-zero entries differing by an odd number. The base code construction is also referred to as order-1 FDPC code.

Extended code construction: In some embodiments, the FDPC code of order s, where s≥2, can be defined by applying s−1 different permutations to the base matrix H_{b}, where permutations can be applied column-wise, and stacking them on top of each other in order to obtain the overall parity-check matrix H for an order-s FDPC code.

MP-PL decoder: In some embodiments, the MP-PL decoder for general noisy channels can be run in multiple stages. The MP decoder utilized in one single stage of the MP-PL decoder can be with the min-sum decoder with weighted updates, where the weight can be set to a small fixed constant. At the end of each stage, the PL decoding component can be activated. In particular, one of the bit indices can be selected and the decoding can proceed across two parallel paths, one with the selected bit being 0, and another one with the selected bit being 1. The index of this bit, a number in the range of 1, 2, . . . , n, is referred to as a path-splitting index.

Path-splitting index selection criterion: In some embodiments, the criterion depends solely on which parity-check equations at the end of the current stage are not yet satisfied. More specifically, in some embodiments, m₁, m₂, . . . , mᵣ, can be set to either 0 or 1, where mᵢ=0 when the i-th parity-check equation (corresponding to the i-th row of H) is satisfied, and mᵢ=1, otherwise. Then the deficiency of the j-th variable node can be defined as the sum of m_{{Ji}}'s, where Ji's are the indices of its neighboring check nodes. The variable node with the maximum deficiency can be selected as the path splitting index.

Proposed path metrics and list pruning: In some embodiments, when the list size, which doubles after each decoding stage, reaches the maximum L (set to 1024 in some embodiments, though the average list size is often much smaller), only L decoding paths with the maximum path metric, as defined later in the “Path metric and list pruning” section, can be pursued for the next stage, and the remaining paths can be discarded.

Checking paths for codewords and stopping point: In some embodiments, for each decoding path at the end of each decoding stage, if all the parity-check equations are satisfied, then the current hard decisions can be set as the decoder output and the decoder stops. Also, in some embodiments, a certain threshold can be set on the number of decoding stages, where the MP-PL decoding algorithm can stop and a block decoding failure can be announced if a codeword is not reached yet. This threshold can be set, e.g., to 16, 20, etc.

Codes defined over sparse structures include, for example, low-density parity-check (LDPC) codes. In general, LDPC codes are specified via a certain sparse structure on the parity-check matrix, e.g., by setting the number of ones in each row and column to be a small fixed number. Consequently, LDPC codes are often designed for fixed moderate-rate codes, e.g., the code rate of 5G LDPC codes is approximately between 1/3 and 8/9.

Besides LDPC codes, alternative codes may also be designed with decoders that are often optimized at moderate rates in order to address diverse and often extreme scenarios in wireless systems. However, ultra-high data rate mmWave and THz links, envisioned for 5G systems and beyond, with precise beam alignment and interference cancellation at the front end lead to an effective high-SNR regime from the decoder's perspective. Also, optical channels exhibit very high SNRs with already low effective bit-error rate (BER) yet necessitating forward error correction (FEC) in order to ensure the target BER requirements are met (typically less than 10⁻⁹ and can be as low as 10⁻¹⁵). Such high-throughput communication scenarios also require very low-latency and low-overhead coding mechanisms, rendering various coding schemes with advanced and complex decoders inapplicable.

In some embodiments of the present disclosure, fair-density parity-check (FDPC) codes targeting high-rate applications are introduced together with a parallelizable and low-complexity variation of MP decoder boosted with a newly proposed progressive list (PL) decoder component, referred to as the MP-PL decoder.

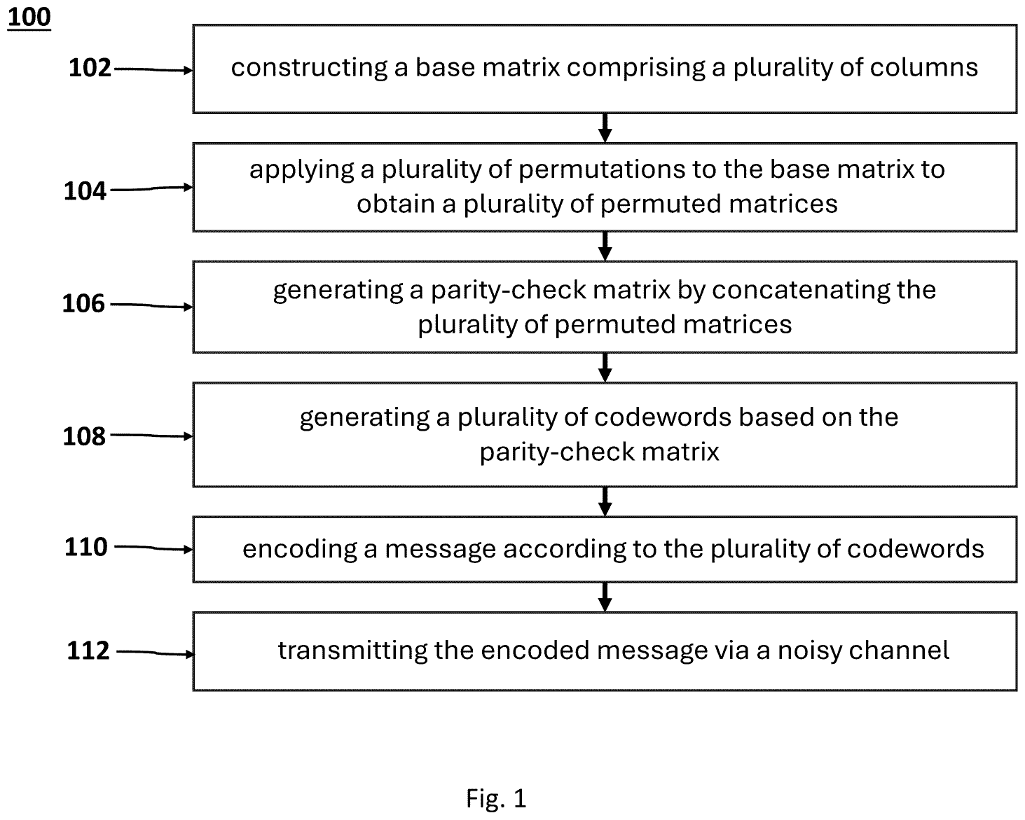

FIG. 1 is a flowchart 100 illustrating an exemplary method according to embodiments of the present disclosure. In some embodiments, at 102, a base matrix is constructed. The base matrix comprises a plurality of columns. In some embodiments, at 104, a plurality of permutations is applied to the base matrix to obtain a plurality of permuted matrices. In some embodiments, at 106, a parity-check matrix is generated by concatenating the plurality of permuted matrices. In some embodiments, at 108, a plurality of codewords is generated based on the parity-check matrix. In some embodiments, at 110, a message is encoded according to the plurality of codewords. In some embodiments, at 112, the encoded message is transmitted via a noisy channel.

Due to the relatively simpler analysis over binary erasure channels (BECs), compared to general noisy channels, typically the first step to study new codes/decoders is to study them over BECs.

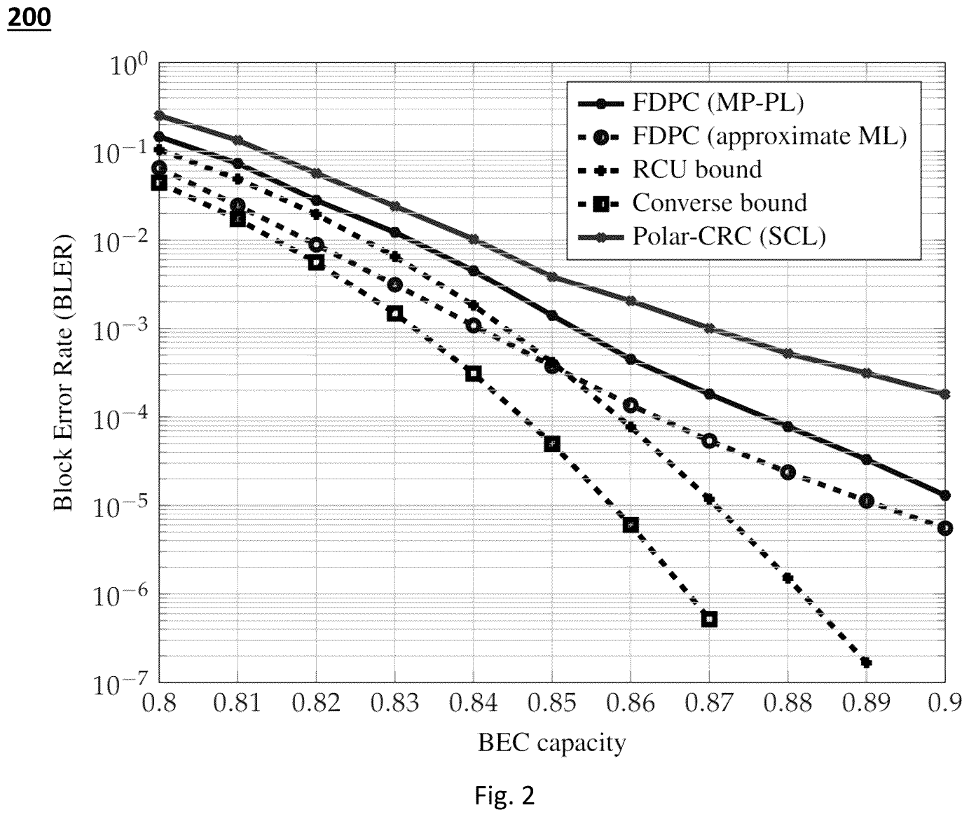

FIG. 2 is a graph 200 illustrating a performance comparison over BECs (n=256, k=195). Specifically, FDPC codes according to embodiments of the present disclosure are compared against fundamental bounds as well as polar-CRC with SCL decoder. CRC is Cyclic Redundancy Check, and SCL is Successive-Cancellation List. Specifically, the performance of a (256, 195) FDPC code according to some embodiments of the present disclosure over BECs with varying erasure probability between 0.1 and 0.2 is demonstrated. For comparison, polar codes are used with a state-of-the-art successive-cancellation list (SCL) decoder aided by a cyclic redundancy check (CRC) decoder (CRC=8, list size L=32). It is observed that FDPC codes, according to some embodiments of the present disclosure, perform better than polar codes in the entire range of considered channel parameters, e.g., by more than one order of magnitude in the block error rate for BEC(0.1). Furthermore, an approximate ML bound for the FDPC codes, averaged over their ensemble, is derived via analytical characterization of their weight distribution. In FIG. 2, a random coding upper bound (RCU bound) and a converse bound are also shown. The FDPC codes closely follow the RCU bound up to the capacity 0.85 but start diverging after that due to their having a small number of low-weight codewords.

A simplified approximation, also referred to as the dispersion bound, is often used to measure the gap between the performance of practical channel codes and what is fundamentally achievable, e.g., with random codes. The dispersion bound provides a closed form approximation for both the RCU and the converse bound, presuming that these two bounds are very close. However, when the code rate is close to zero or one, the approximation may become inaccurate. This phenomenon can be characterized in depth for low-rate channel coding, and, as can be seen in FIG. 2, the RCU and converse bound can actually differ by one order of magnitude especially as the capacity gets closer to one.

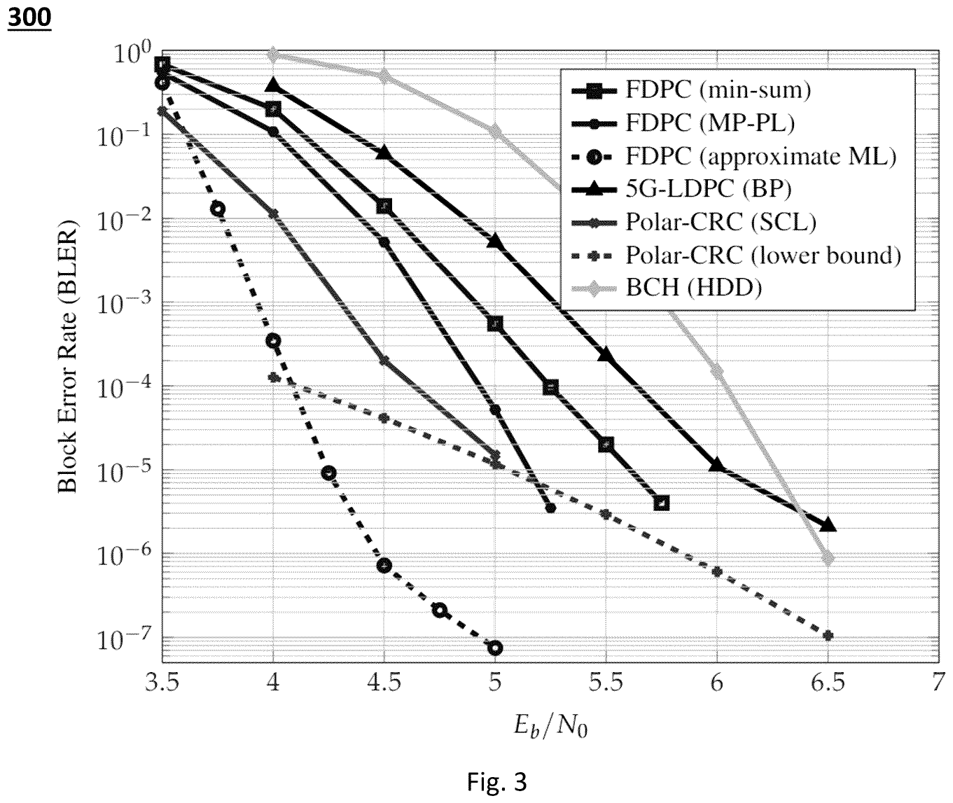

FIG. 3 is a graph 300 illustrating a performance comparison over B-AWGN (n=1024, rate=0.878). Specifically, FDPC codes according to embodiments of the present disclosure are compared against 5G-LDPC, polar CRC and BCH codes. Specifically, the performance of (1023, 898) FDPC codes according to some embodiments of the present disclosure, constructed with n=1024 and shortened by 1 bit due to weight distribution considerations that are discussed later in the “Weight Distribution” section, over binary-input additive white Gaussian noise (B-AWGN) channels is shown. The FDPC code with the plain min-sum decoder (e.g., no offsetting, weighting, nor parameter tuning) performs better than the 5G-LDPC code under the belief propagation (BP) decoding by about 0.5 dB. Furthermore, the LDPC code starts to show an error floor at block error rate (BLER)≈10⁻⁵, but the FDPC code is not expected to hit an error floor until 10⁻⁶ BLER or lower (given the simulations and the ML approximation curve). In fact, the exact characterization of the minimum distance and the weight distribution for the low-weight codewords of FDPC codes allows for the precise prediction of the error floor performance.

It is also observed that the performance of the FDPC code can be boosted since there is a considerable gap between the min-sum performance curve and the approximate ML curve. To this end, we propose a parallelizable and low-complexity variation of min-sum message passing (MP) decoder coupled with a newly proposed progressives list (PL) decoder component, referred to as the MP-PL decoder. The MP component in the MP-PL decoder is with the min-sum approximation, one of the simplest possible forms of message passing. The decoder performance is about 1 dB away from the approximate ML bound of FDPC codes, mainly due to the simplicity of its MP component, with the major advantage of enabling a low-complexity low-latency implementation. For instance, no multiplication/division of log-likelihood ratios (LLRs) are involved in the decoder. The only operations involved are addition/comparison of LLRs as well as scaling them by a fixed constant. The FDPC code with this variation of MP-PL decoder performs worse (about 0.5 dB) than a polar-CRC code with SCL decoder (CRC=8, L=32) in lower SNRs. Nevertheless, FDPC provides a sharper curve at higher SNRs and the FDPC code with MP-PL decoder beats polar-CRC with SCL decoder (CRC=8, L=32) in lower SNRs at BLER<10⁻⁵. For this comparison, a lower bound is used on the performance of polar-CRC. The lower bound is derived by only counting the number of codewords with weight equal to the minimum distance. Also, at this BLER, the MP-PL decoder is, on average, 50 times less complex and 800 times faster in latency, compared with SCL, the details of which are discussed later in the “Decoding Complexity and Latency” section. At this SNR, the MP-PL decoder is, on average, 18 times less complex and 190 faster in latency, compared with SCL, the details of which are discussed later in the “Decoding Complexity and Latency” section. The lower bound for the polar-CRC is for any decoder, including the ML decoder, and indicates that with ML decoder FDPC code is a better code than polar-CRC at least for BLER<10⁻⁴.

The performance of BCH code with hard-decision decoding (HDD) is also shown in FIG. 3, that is about 1 dB worse than that of FDPC codes. There are soft-decision based decoders that have been utilized for BCH codes, e.g., ordered statistics decoders, however, such decoders are often only used in shorter block lengths and lower rates due to complexity reasons.

### Code Construction

### Base Matrix

Let n=4t², for some integer t≥2. Then, in some embodiments of the present disclosure, the base parity-check matrix H_{b} can be constructed as follows.

Definition 1: The matrix H_{b} consists of all binary column-vectors of length 4t and Hamming weight two with the indices of the two non-zero entries differing by an odd number.

All rows of H_{b} have weight 2t.

Example 1. For t=2, the matrix H_{b} is given as follows:

$$[ \begin{matrix}1 & 1 & 0 & 0 & 0 & 0 & 0 & 0 & 0 & 0 & 0 & 1 & 0 & 0 & 1 & 0 \\ 1 & 0 & 1 & 1 & 0 & 0 & 0 & 0 & 0 & 0 & 0 & 0 & 0 & 1 & 0 & 0 \\ 0 & 0 & 1 & 0 & 1 & 1 & 0 & 0 & 0 & 0 & 0 & 0 & 0 & 0 & 0 & 1 \\ 0 & 1 & 0 & 0 & 1 & 0 & 1 & 1 & 0 & 0 & 0 & 0 & 0 & 0 & 0 & 0 \\ 0 & 0 & 0 & 1 & 0 & 0 & 1 & 0 & 1 & 1 & 0 & 0 & 0 & 0 & 0 & 0 \\ 0 & 0 & 0 & 0 & 0 & 1 & 0 & 0 & 1 & 0 & 1 & 1 & 0 & 0 & 0 & 0 \\ 0 & 0 & 0 & 0 & 0 & 0 & 0 & 1 & 0 & 0 & 1 & 0 & 1 & 1 & 0 & 0 \\ 0 & 0 & 0 & 0 & 0 & 0 & 0 & 0 & 0 & 1 & 0 & 0 & 1 & 0 & 1 & 1\end{matrix} ]$$

Lemma 1: The binary rank of H_{b} is 4t−1. Furthermore, the code C_{b} with H_{b} as its parity-check matrix has minimum distance dₘᵢₙ(C_{b})=4.

Proof: The sum of all rows of H_{b} equals zero. Hence, rank(H_{b})≤4t−1. Now, suppose that the sum of a subset S of rows of H_{b} is zero. Consider the Tanner graph G representing the parity-check matrix H_{b}. Then any two variable nodes in G connecting via a check node must either both appear in S or both not appear in S (since the column weights of H_{b} are exactly two). Since G is connected, then the only non-trivial possibility for Sis the set of all rows of H_{b}. This implies rank(H_{b})=4t−1.

With regard to dₘᵢₙ(C_{b}), columns of H_{b} are distinct and no three of them sum up to zeros. The latter is due to the property of H_{b} that the non-zero entries in any of its columns differ by an odd number. There are selections of four columns of H_{b} summing to zeros. Hence, dₘᵢₙ(C_{b})=4.

### Expanding Via Random Permutations and Cascading

Let s≥2. Then, in some embodiments, the FDPC code of order s can be defined by applying s−1 different permutations to the base matrix H_{b}, where permutations are applied column-wise, and stacking them on top of each other in order to obtain the overall parity-check matrix H. More specifically, let π₁, . . . , πₛ₋₁ be distinct permutations on the set [n]:={1, 2, . . . , n}. Then the parity-check matrix H for the order-s FDPC code associated with this set of permutations is given as follows:

$$H = {[ \begin{matrix}{H}_{b} \\ {π}_{1} ( {H}_{b} ) \\ ⋮ \\ {π}_{s - 1} ( {H}_{b} )\end{matrix} ]}_{r \times n} \qquad ( 1 )$$

where r=2s\sqrt{n}=4st. The rows of H may not be linearly independent. Hence, the dimension of an order-s FDPC code is greater than or equal to n−r+s. As an example, in the case of order-2 FDPC codes, there is simply one permutation π, and the parity-check matrix H is the result of stacking H_{b} and π(H_{b}) on top of each other.

### Weight Distribution and ML Bound

### Weight Distribution

In some embodiments, the weight distribution for the order-1 FDPC code C_{b} with H_{b} as its parity-check matrix is derived as follows. To this end, the Tanner graph G_{b} representing H_{b}, where variable nodes are indexed by 1, 2, . . . , n, and check nodes are indexed by 1, 2, . . . , r, where r=4t, is considered. Then the following lemma describes a certain property of codewords in C_{b}.

Lemma 2: Let c=(c₁, c₂, . . . , cₙ) be a non-zero codeword of weight w in C_{b}. Let I_{c}={i₁, i₂, . . . , i_{w}} denote its support, e.g., the indices of non-zero entries in c, and consider the subgraph G_{b}′⊆G_{b} induced by variable nodes i₁, i₂, . . . , i_{w} and their neighbors. Then G_{b}′ is either a loop or a collection of non-overlapping loops.

Proof: The columns of H_{b} indexed by indices in I_{C} sum up to zeros. Consider iⱼ∈I_{c} and let j₁ and j₂ denote the indices of non-zero entries in the iⱼ-th column of H_{b}. Then there must be at least one other variable node in I_{c} (more precisely, an odd number of them), other than iⱼ, that is connected to the check node j₁. The same is true for the check node j₂. Then we follow the same argument for these two until we eventually reach a loop (since some variable node will be eventually revisited). This loop is contained in G_{b}′, and we can remove it from G_{b}′ and repeat the same argument for what is left in G_{b}′. This concludes the proof.

Example 2. Consider the code C_{b} with parameter t=2, as presented in Example 1. Then the vector (1, 1, 1, 0, 1, 0, 0, 0, 0, 0, 0, 0, 0, 0, 0, 0) is a codeword in C_{b}. The sub-graph induced by columns indexed by 1, 2, 3, 5 consists of all edges connecting variable nodes 1, 2, 3, 5 and check nodes 1, 2, 3, 4, which is a loop of length 8.

Definition 2: A codeword in the order-1 FDPC code C_{b} is irreducible if its corresponding induced sub-graph G_{b}′, as discussed in Lemma 2, consists of a single loop. For instance, the codeword presented in Example 2 (or any other codeword of weight 4 or 6) is an irreducible codeword.

If a codeword c is not irreducible, then it can be written as a sum of irreducible codewords with non-overlapping supports. This collection of irreducible codewords is referred to as a base for the codeword c, which is unique for each codeword. There are irreducible codewords of any even weight between 4 and 4t, which is the maximum possible length for irreducible codewords. The next lemma presents the exact number of irreducible codewords of any given weight.

Lemma 3: Let m with 4≤m≤4t be an even integer. Then there exists

$${A}_{m}^{( ir )} {=}^{def} {\prod }_{i = 0}^{m / 2 - 1} {( 2 t - i )}^{2} / m \qquad ( 2 )$$

irreducible codewords of weight m in C_{b}. For any other m, there exists no irreducible codeword of weight m.

Proof: The proof is by following counting arguments.

For w∈[n], let A_{w} denote the number of codewords of weight w in the code C_{b}. The next lemma builds upon Lemma 3 in order to obtain bounds on the weight distribution coefficients A_{w}'s.

Proposition 4: For any n and w≤n we have

$${A}_{w} \leq {\sum }_{{a}_{m}^{′} s} {\prod }_{m} ( \begin{matrix}{A}_{m}^{( ir )} \\ {a}_{m}\end{matrix} ) \qquad ( 3 )$$

where the summation is over all non-negative integers a₄, a₆, . . . , α₄ₜ with Σₘ₌₄^{4t}maₘ=w.

Proof: The upper bound is obtained by upper bounding the number of all possible collections of irreducible codewords that form a base for a codeword of weight w.

The upper bound in Proposition 4 can be improved by excluding the counted instances of collections of irreducible codewords where some of them overlap with each other. Taking into account such an improvement results in a cumbersome, yet computable, upper bound which is used when presenting the numerical upper bounds on the performance of ML decoder utilizing the upper bounds on the weight distribution of the code.

Next, consider the ensemble of all FDPC codes of length n=4t² and order s. In particular, s=2 is considered but the results on the weight distribution can be extended to general s in a straightforward fashion.

Suppose that the permutation π in the construction of the order-2 FDPC code is selected uniformly at random, and let A_{w}⁽²⁾ denote the random variable representing the number of codewords of weight w in the resulting code. Then the expected value of the weight, denoted by ε{A_{w}⁽²⁾}, averaged over all permutations is given as follows:

$$ℰ \{ {A}_{w}^{( 2 )} \} = \frac{{A}_{w}^{2}}{( \begin{matrix}n \\ w\end{matrix} )} \qquad ( 4 )$$

Example 3: For w=4, combining (4) with Lemma 3 and straightforward computations leads to

$$ℰ \{ {A}_{4}^{( 2 )} \} = \frac{3 {n ( \sqrt{n} - 1 )}^{4}}{2 ( n - 1 ) ( n - 2 ) ( n - 3 )} < \frac{3}{2} \qquad ( 5 )$$

And, similarly, for w=6 we have

$$ℰ \{ {A}_{6}^{( 2 )} \} = \frac{20 {n ( \sqrt{n} - 1 )}^{4} {( \sqrt{n} - 2 )}^{4}}{( n - 1 ) ( n - 2 ) ( n - 3 ) ( n - 4 ) ( n - 5 )} < 20 \qquad ( 6 )$$

Remark 1. Example 3 demonstrates that the average number of low-weight codewords in the random ensemble of FDPC codes is a small constant. This can be leveraged to easily increase the minimum distance of the code by shortening it, something that can significantly improve the code performance in the error floor region. For instance, by carefully shortening the code by 1 bit, FDPC codes of minimum distance at least 6 are obtained with high probability. Shortening an (n, k) code by t bits results in an (n−t, k−t) code, which may have a negligible effect on the rate for high-rate codes and small values of t. For instance, shortening an order-2 FDPC code of length 2¹⁰, a (1024, 899) code, by 20 bits results in a (1004, 879) code reducing the rate only by 0.0024 from 0.8779 to 0.8755. The FDPC code with the performance shown in FIG. 3 is shortened by 1 bit to eliminate its only weight-4 codeword, resulting in a (1023, 898) code.

Remark 2. In this remark, the process of shortening the codes in the ensemble is discussed more explicitly. For instance, consider the weight w=4 and suppose the aim is to shorten the FDPC codes by α₄ bits, corresponding to weight-4 codewords. For each FDPC code C in the ensemble with at least α₄ codewords, we remove one column from the parity-check matrix with the index corresponding to a non-zero entry of one of the weight-4 codewords. This shortening process will reduce the number of weight-4 codewords by at least α₄. If the number of weight-4 codewords in an FDPC code in the ensemble is less than α₄, one can still shorten the code by α₄ bits and ensure that no weight-4 codeword remains in the code. One can continue the shortening process, in a similar fashion, with α₆ bits corresponding to weight-6 codewords, etc.

### ML Bound

In this section, bounds on the probability of error of the maximum likelihood (ML) decoder for FDPC codes, according to some embodiments of the present disclosure, are derived. Communication over BEC (E) is considered. The following union-type upper bound holds on the probability of error of the ML decoder, denoted by Pₑ^{(ML)}, for any linear code \tilde{C}:

$${P}_{e}^{( ML )} \leq {\sum }_{w = {d}_{min}}^{n} {\tilde{A}}_{w} {ϵ}^{w} \qquad ( 7 )$$

where {Ã_{w}:w=dₘᵢₙ, . . . , n} denote the weight distribution of \tilde{C}, and dₘᵢₙ is the minimum distance of \tilde{C}. The reasoning behind this bound is as follows. Given an erasure pattern ε the ML decoder fails if and only if there is a non-zero codeword c in \tilde{C} whose support is a subset of the erasure positions. And the bound in (7) is a union bound on the probability that the set of erasure positions contain a codeword, where the union bound is taken with respect to all possible codewords. However, this upper bound, with all the terms therein, may become numerically inaccurate to compute as each term Ã_{w}ϵ^{w} is the product of two terms, with one decaying exponentially small and then the other one growing exponentially large. Therefore, instead of the whole expression in (7), a common approach is to consider a threshold wₜ and compute the expression only up to the wₜ-th term. For a properly chosen value of wₜ, this gives a precise approximation for the performance of the ML decoder. This is often referred to as an approximate union bound on the performance of ML decoder.

For the ensemble of FDPC codes, say the order-2 one, one could take the expected value from both sides of (7) and arrive at

$$ℰ \{ {P}_{e}^{( ML )} \} \leq {\sum }_{w = 4}^{n} ℰ \{ {A}_{w}^{( 2 )} \} {ϵ}^{w} \qquad ( 8 )$$

The next lemma discusses how this upper bound can be revised for the ensemble of shortened FDPC codes.

Proposition 5: For w=4, 6, . . . , 2(d−1), for some integer d>2, consider integers α_{w}≥└ε{A_{w}⁽²⁾}┘. Consider the ensemble of shortened FDPC codes by Σᵢ₌₂^{d-1}α₂ᵢ bits and minimum distance d, where α₂ᵢ columns of H are eliminated, reducing the number of weight-2i codewords by α₂ᵢ. Let

$$γ = {\sum }_{i = 2}^{d - 1} \frac{ℰ \{ {A}_{2 i}^{( 2 )} \}}{{α}_{2 i} + 1} \qquad ( 9 )$$

and assume that γ<1. Then the average probability of ML decoder over the ensemble of FDPC codes with dₘᵢₙ≥2d is upper bounded as follows:

$$ℰ \{ {P}_{e}^{( ML )} \} \leq \frac{1}{1 - γ} {\sum }_{w = 2 d}^{n} ℰ \{ {A}_{w}^{( 2 )} \} {ϵ}^{w} \qquad ( 10 )$$

Proof: For any w, using Markov inequality, the probability that a random FDPC code has more than α_{w} codewords of weight w is upper bounded by

$$\frac{ℰ \{ {A}_{w}^{( 2 )} \}}{{α}_{w} + 1} .$$

Then by taking the union bound across all w's, for w=4, 6, . . . , 2(d−1), the probability that an FDPC code has a codeword of weight less than 2d, after shortening by Σᵢ₌₂^{d-1}α₂ᵢ bits, is upper bounded by γ. Hence, at least a fraction of 1−γ of FDPC codes have minimum distance d and the expected value of codewords of weight w≥d over these codes is at most

$$\frac{1}{1 - γ} ℰ \{ {A}_{w}^{( 2 )} \} .$$

The rest of the proof is the same as the proof for the original upper bound in (7).

The approximate ML bound of the ensemble of FDPC codes shown in FIG. 2 is with wₜ=20, e.g., weight distribution is taken into account up to codewords of weight 20 in (10). Also, they are shortened by α₄=1 bit and have dₘᵢₙ≥2d=6.

For transmission over B-AWGN with noise variance σ², an upper bound on the performance of the ML decoder, similar to the one in (7), holds:

$${P}_{e}^{( ML )} \leq {\sum }_{w = {d}_{min}}^{n} {\tilde{A}}_{w} Q ( \frac{\sqrt{w}}{σ} ) \qquad ( 11 )$$

where, again, a linear code \tilde{C} with weight distribution {Ã_{w}:w=dₘᵢₙ, . . . , n} is considered for transmission. Also, Q(⋅) is the q-function representing the tail of the cumulative probability distribution of normal Gaussian distribution.

Also, similarly, the result in Proposition 5 can be revised to get an upper bound on the probability of ML decoder for shortened FDPC codes for transmission over the B-AWGN channel:

$$ℰ \{ {P}_{e}^{( ML )} \} \leq \frac{1}{1 - γ} {\sum }_{w = 2 d}^{n} ℰ \{ {A}_{w}^{( 2 )} \} Q ( \frac{\sqrt{w}}{σ} ) \qquad ( 12 )$$

where γ is defined in (9), and dis as defined in Proposition 5. The approximate ML bound of the ensemble of FDPC codes shown in FIG. 3 is with wₜ=30, e.g., weight distribution is taken into account up to codewords of weight 30 in (12). Also, they are shortened by α₄=1 bit and have

$${d}_{min} \geq 2 d = 6.$$

### MP-PL Decoding Algorithm

In this section, the proposed MP-PL decoding algorithm to boost the performance of FDPC codes, according to some embodiments of the present disclosure, is presented. This is done separately for BEC channels and the general class of noisy channels, due to the very different nature of how erased/erroneous bits are decoded in an MP-type decoding for these channels. A major building block of the decoding algorithm, in both cases, is a variation of iterative message-passing (MP) decoding algorithm. Another major building block, which is the main novel component, is a progressive list decoder that is combined with multiple stages of the MP decoder to form the MP progressive list (MP-PL) decoder, which will be discussed in detail in this section.

### MP-PL Decoding Algorithm for BEC

Let c=(c₁, c₂, . . . , cₙ) denote the transmitted codeword, which is received at the receiver with some erasures (e.g., a certain number of coded bits are erased). The MP-PL decoder is run in multiple stages, to be discussed next.

Standard MP decoder for BEC. In each iteration of the MP decoder, any erased variable node which connects to a check node whose other variable node neighbors are already decoded and known, will be turned from erasure to a successfully decoded bit. More specifically, consider an erased bit cᵢ_{₁} and a parity-check equation involving cᵢ_{₁}, e.g.,

$${c}_{{i}_{1}} + {c}_{{i}_{2}} + … + {c}_{{i}_{2 t}} = 0.$$

As highlighted above in the description of constructing a base matrix, all rows of H have weight equal to 2t. Then if all other cᵢ_{ⱼ}'s, j=2, . . . , 2t, are already known/decoded, then cᵢ_{₁} is also decoded. And the same procedure applies to all variable nodes at once in each iteration.

A single stage in the MP-PL decoder. In each stage, the standard MP decoder is utilized repeatedly for a certain number of iterations λᵢₜ (for example, λᵢₜ=4 is set in the simulations shown in the Figures), or until it saturates, e.g., when no new erasure is decoded from one iteration to the next, whichever comes first. At this point, the PL decoding component is initiated. In particular, one of the erasures that is not decoded yet is selected, say cⱼ_{ᵢ}, in the i-th stage, and then the MP decoding continues along the two possible paths, one with cⱼ_{ᵢ}=0 and another one with cⱼ_{ᵢ}=1 in the stage i+1. We refer to jᵢ as the i-th path-splitting index. This doubles the list size as the MP-PL decoder transitions to the next stage. If at any point in the decoding process of a path, an erasure variable node gets two inconsistent decoded results from two neighboring check nodes, that path will be discarded as this indicates that at some point along the progressive list decoding a wrong choice is pursued when splitting the paths.

Path-splitting index selection criterion. The criterion solely depends on the location of current erasures in the current path. Let Hₑ denote a sub-matrix of the parity-check matrix H by selecting columns of H corresponding to the current erasures. Let m₁, m₂, . . . , mᵣ denote the number of ones in rows of Hₑ, where r is the number of rows in both H and Hₑ. Let m_{i′} be the minimum non-zero value in the set {mᵢ:i∈[r]}. Then jᵢ is selected as the index of one of the non-zero entries in the i′-th row of H that corresponds to a current erasure.

Remark 3. Roughly speaking, the logic behind the selection of the path-splitting indices is to increase the chances of recovering from more erasures when further applying the MP decoding iterations. For instance, if m_{i′}=2, then the way the current path-splitting index is selected ensures that at least another erasure will be corrected in the next iteration of the MP decoder.

The MP-PL decoder outcome. Let L=2^{l} denote the maximum list size. Then the MP-PL decoder continues up to the l-th stage, or until all erasures are decoded in at least one decoding path, whichever comes first. If there is more than one path in which all erasures are corrected, it implies that there is more than one codeword that matches with all the non-erased received bits. In other words, the transmitted codeword is not uniquely decodable for such an erasure pattern scenario.

Algorithm 1 MP-PL Decoding Algorithm for BECs

| Input: Channel output y as a codeword c with a certain subset | |
|---|---|
| of entries erased; the parity-check matrix H_{r×n}; maximum list | |
| size L = 2^{l}; maximum iterations per stage λᵢₜ. | |
| Output: transmitted codeword c | |
| Available functions: MP-iter-BEC: one single iteration of MP | |
| decoder over BEC, with inputs y, H and output y′; | |
| Path-split-ind: selecting the path-splitting index, with input y | |
| and H, and output index j. | |
| 1: | initialize: \tilde{L} = 1, y₁ = y. |
| 2: | while \tilde{L} < L, c not found do |
| 3: | for i = 1, 2, ... , \tilde{L} do |
| 4: | for j = 1, 2, ... , λᵢₜ do |
| 5: | yᵢ = MP-iter-BEC(yᵢ, H) |
| 6: | if yᵢ has no erasure then |
| 7: | c = yᵢ and break |
| 8: | end if |
| 9: | end for |
| 10: | j = Path-split-ind(yᵢ, H) |
| 11: | y_{\tilde{L}+i} = yᵢ |
| 12: | yᵢ(j) = 0 |
| 13: | y_{\tilde{L}+i} (j) = 1 |
| 14: | end for |
| 15: | \tilde{L} = 2\tilde{L} |
| 16: | end while |

A brief pseudo-code for the MP-PL decoder, while skipping some detailed steps, is presented as Algorithm 1 above. Some of the omitted details include killing decoding paths where some variable nodes received inconsistent messages in the MP decoder, and handling cases with multiple output codewords.

### MP-PL Decoding Algorithm for General Noisy Channels

The MP-PL decoder for general noisy channels can also be run in multiple stages, same as in the BEC case. However, the criterion for selecting path-splitting indices and how to efficiently check if a codeword is obtained are different. The latter does not apply to the BEC case as all decoding paths are equally likely as long as there is no inconsistency in their MP updates. The MP decoder utilized in some embodiments in one single stage of the MP-PL decoder is with the min-sum decoder with weighted updates. Also, in some embodiments, inspired by the SCL decoding of polar codes, a list pruning strategy can be adopted by comparing a certain metric associated with the decoding paths.

Weighted min-sum MP decoder. In this decoder, all message updates are done while scaled with a small fixed constant β, e.g., β=0.05. Furthermore, the LLRs of the coded bits continue to be updated in each round. More specifically, let y^{(cur)}=(y₁^{(cur)}, . . . , yₙ^{(cur)}) denote the current soft information for the coded bits c=(c₁, . . . , cₙ) in the LLR domain. Let also q_{i,j}^{(cur)} (and r_{j,i}^{(cur)}) denote the current message passed from the i-th variable node to the j-th check node, (and vice versa) when H(j, i)=1. Then the updated soft information yᵢ^{(new)}, q_{i,j}^{(new)}, and r_{j,i}^{(new)} of the i-th coded bit are as follows:

$${r}_{j , i}^{( new )} = {\prod }_{{i}^{′} ∈ {V}_{j \backslash i}} sign ( {q}_{{i}^{′} , j}^{( cur )} ) {min}_{{i}^{′} ∈ {V}_{j \backslash i}} \vert {q}_{{i}^{′} , j}^{( cur )} \vert , \qquad ( 13 )$$

$${y}_{i}^{( new )} = {y}_{i}^{( cur )} + β {\sum }_{j , H ( j , i ) = 1} {r}_{j , i}^{( new )} , \qquad ( 14 )$$

$${q}_{i , j}^{( new )} = {y}_{i}^{( new )} - β {r}_{j , i}^{( new )} , \qquad ( 15 )$$

where [symbol] :={i′:i′≠i, H(j, i′)=1} and β is a fixed constant that is referred to as the weight in the weighted min-sum MP decoder. For example, β can be set to be a small value, e.g., β=0.05 is set in the simulations shown in the Figures. All soft information is updated at once in each iteration. In a sense, this version of MP decoding keeps accumulating all the previously generated LLRs in prior iterations while scaling them down in order to not having the accumulated LLRs saturate quickly.

Remark 4. As it is evident from (14), the scaling of yᵢ's does not affect the decoder. Hence, in cases such as the AWGN or fading channels, the plain channel output can be used as the input to the MP-PL decoder in the first stage. This gives an advantage, especially in non-coherent settings, over most soft-decision decoders which require the knowledge of the channel, e.g., the channel gain and noise variance, in order to generate the LLRs to be fed into the decoder.

Path-splitting index selection criterion. The proposed criterion depends solely on which parity-check equations at the end of the current stage are not yet satisfied. More specifically, let m₁, m₂, . . . , mᵣ, with mᵢ∈{0, 1}, where mᵢ=0 when the i-th parity-check equation (corresponding to the i-th row of H) is satisfied, and mᵢ=1, otherwise. Then the deficiency of the j-th variable node is defined as the sum of mⱼ_{ᵢ}, over jᵢ in the set of the indices of its neighboring check nodes. The variable node with the maximum deficiency is selected as the path-splitting index.

In the simulations shown in the Figures, the number of path splittings has been limited to 16, e.g., the maximum list size is 2¹⁶. List-pruning strategies can be adopted, same as in the SCL decoding of polar codes, to ensure the list size remains small. Also, this is the worst case scenario, and the average list size is much smaller (e.g., close to 1 for high-SNRs). Also, as shown in FIG. 3, the min-sum decoder already performs well. Hence, the list decoding component, which is activated only when the min-sum fails, is only run for a small fraction of time.

Path metric and list pruning. Let yᵢ^{(rec)} and yᵢ^{(cur)} denote the received and the current soft information for the coded bit cᵢ, for i∈[n]. Then the current path metric can be computed as follows:

$${\sum }_{i ∈ [ n ]} sign ( {y}_{i}^{( cur )} ) \times {y}_{i}^{( rec )}$$

When the list size reaches the maximum L (set to 1024 in the simulations shown in the Figures, though the average list size is often much smaller), only L decoding paths with the maximum path metric, as defined above, are pursued for the next stage.

Checking paths for codewords and stopping point. For each decoding path at the end of each decoding stage, if all the parity-check equations are satisfied, then the current hard decisions can be set as the decoder output and the decoder can stop. Also, a certain threshold can be set on the number of decoding stages, where the MP-PL decoding algorithm stops and a block decoding failure is announced if a codeword is not reached yet. This threshold is set to 20 in the simulations shown in the Figures.

### Decoding Complexity and Latency

Let the complexity of comparison, addition, and multiplication/division in the soft information/LLR domain be denoted by μ_{c}, μₐ, and μ_{d}, respectively, where the unit can be one logical bit operation. Similarly, let the latency of comparison, addition, and multiplication/addition be denoted by υ_{c}, υₐ, and υ_{d}, respectively, where the unit could be the delay of one logical bit operation. In each iteration, for each parity-check node, the first and the second minimum over its neighboring variable nodes need to be computed. This is done with the complexity of 2\sqrt{n}μ_{c}, and latency of 2 log nυ_{c}. Each variable node update is done with the complexity of 2sμₐ and latency of (log s+2)υₐ for an order-s FDPC code. Then the total complexity of each iteration is 2sn (2μ_{c}+μₐ). Assuming full parallelization of all variable and check node operations, which can be done in principle, the total latency of each iteration is 2 log nυ_{c}+ (log s+2)υₐ. Since all parameters other than n can be treated as constants, the complexity and latency of each iteration are essentially O(n) and O(log n), respectively. With list-decoding, the average complexity of the MP-PL decoder scales with the average of L, but not the latency.

To arrive at the complexity/latency comparisons reported above, consider that the SCL decoding of polar codes has complexity and latency of O(Ln log n) and O(n), respectively. More specifically, the complexity is nL log n(μ_{d}+μₐ) and the latency is n(2υ_{d}+υₐ). Then assuming a fixed-point implementation with 8 bits, μ_{d}≈8μₐ, μₐ≈2μ_{c} can be used, where similar relations hold also for υ_{c}, υₐ, and υ_{d}. The exact numbers depend on the actual hardware implementation, however, it is expected that the numbers stay in the same range. With these rough estimates, the complexity comparisons reported above are arrived at. The average number of iterations and list sizes in MP-PL decoder of FDPC codes at SNR=5.25 dB with the performance reported in FIG. 3 (where it starts to beat polar-CRC with SCL) are used. More specifically, for the experiments shown in FIG. 3, the average list size is L_{avg}≈1.63, and the average number of iterations per sample (taking into account all paths in the list) is ≈5.

### Further Simulation Results

In addition to the simulation results provided above, in this section, a scenario is studied in the large block length regime, e.g., with n=16384. In this regime, mainly suitable for optical applications, the latency considerations call for highly parallelizable decoders. As a result, product codes and their other variations, including staircase codes, are examples of codes applicable in this regime.

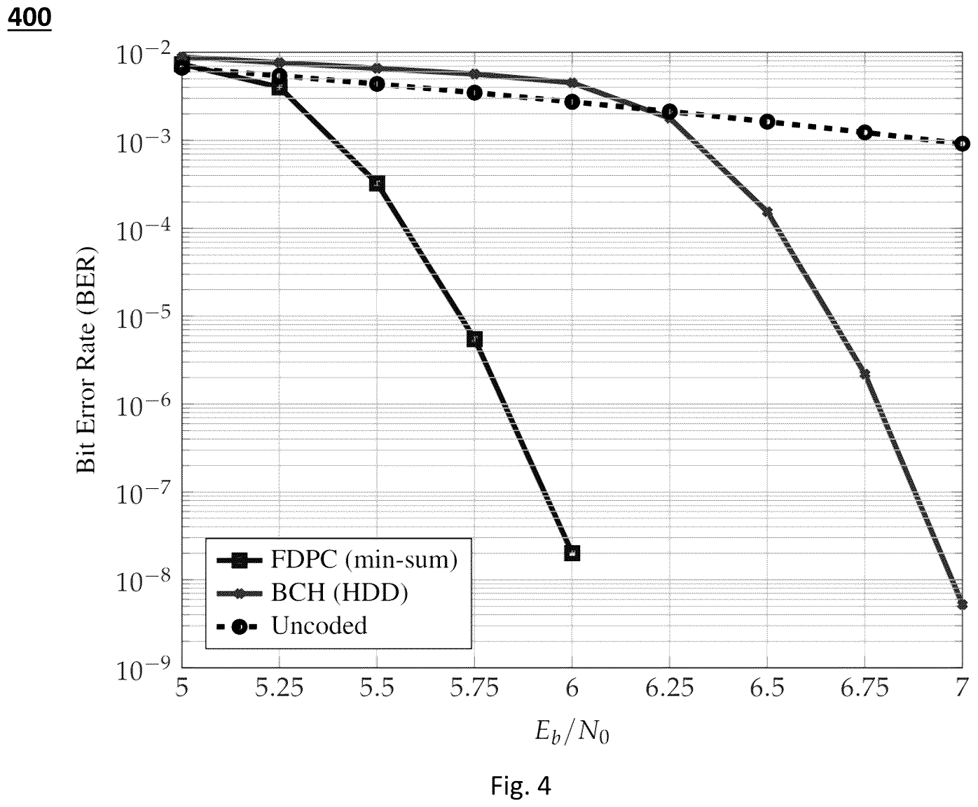

FIG. 4 is a graph 400 illustrating a performance comparison over B-AWGN (n=16384, rate=0.97) according to embodiments of the present disclosure. In this set of experiments, an order-2 FDPC code is constructed at block length n=16384 with rate≈0.97. Constructing such a high-rate code cannot be accomplished with a reasonable product coding architecture. In fact, even if one considers a product code with (256, 247) extended Hamming code as its two components, the overall rate would be ≈0.93. Codes of such a high rate, e.g., rate 0.97, at this regime have not been studied in the literature. Nevertheless, just to show a baseline in FIG. 4, algebraic BCH codes were chosen with HDD decoder. Polar codes become largely impractical in this regime due to the high-latency of SC-type decoders. The bit-error rate (BER), often considered as the figure of merit in optical settings, of the FDPC code is shown in FIG. 4. It is observed that the FDPC code, with the plain min-sum decoder (no list), is ≈1 dB better than the BCH code of the same length and rate.

Even though it is difficult to obtain simulations results at very low BERs (e.g., BER=10⁻¹²), relevant for optical applications, using Monte Carlo simulations, the error floor region of FDPC codes can at least be commented on. The BLER performance of a code in its error floor region is mainly dominated by the A_{d}_{ₘᵢₙ}Q(\sqrt{dₘᵢₙ}/σ) term. With dₘᵢₙ=6, and A_{d}_{ₘᵢₙ}<20, as in (6), the value of A_{d}_{ₘᵢₙ}Q(\sqrt{dₘᵢₙ}/σ) is approximately 10⁻¹⁰ at 6 dB and 2×10⁻¹³ at 7 dB, for FDPC codes. This together with the curve shown in FIG. 4 indicates that the error floor of FDPC code happens at a very low error rate regime, e.g., when BLER<10⁻¹³ (or anticipated BER<10⁻¹⁶).

The results and discussions in this section demonstrate that FDPC codes are suitable for optical applications in high-rate large block length regimes.

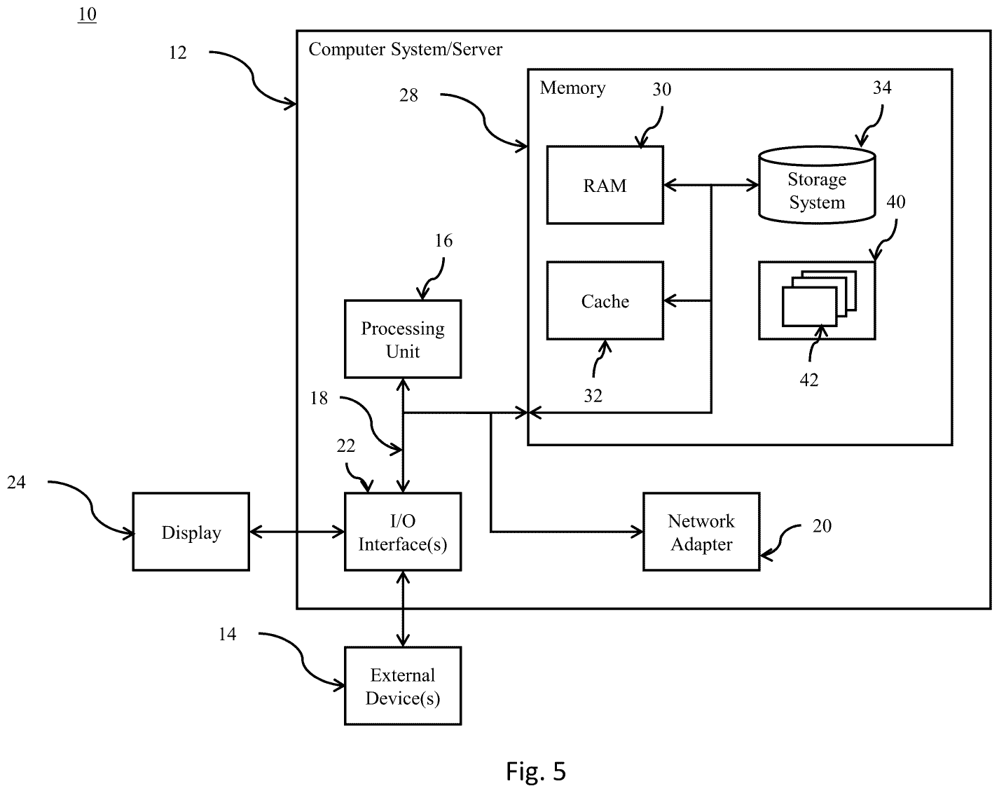

FIG. 5 is a schematic illustrating an example of a computing node according to embodiments of the present disclosure. Computing node 10 is only one example of a suitable computing node and is not intended to suggest any limitation as to the scope of use or functionality of embodiments described herein. Regardless, computing node 10 is capable of being implemented and/or performing any of the functionality set forth hereinabove.

In computing node 10 there is a computer system/server 12, which is operational with numerous other general purpose or special purpose computing system environments or configurations. Examples of well-known computing systems, environments, and/or configurations that may be suitable for use with computer system/server 12 include, but are not limited to, personal computer systems, server computer systems, thin clients, thick clients, handheld or laptop devices, multiprocessor systems, microprocessor-based systems, set top boxes, programmable consumer electronics, network PCs, minicomputer systems, mainframe computer systems, and distributed cloud computing environments that include any of the above systems or devices, and the like.

Computer system/server 12 may be described in the general context of computer system-executable instructions, such as program modules, being executed by a computer system. Generally, program modules may include routines, programs, objects, components, logic, data structures, and so on that perform particular tasks or implement particular abstract data types. Computer system/server 12 may be practiced in distributed cloud computing environments where tasks are performed by remote processing devices that are linked through a communications network. In a distributed cloud computing environment, program modules may be located in both local and remote computer system storage media including memory storage devices.

As shown in FIG. 5, computer system/server 12 in computing node 10 is shown in the form of a general-purpose computing device. The components of computer system/server 12 may include, but are not limited to, one or more processors or processing units 16, a system memory 28, and a bus 18 that couples various system components including system memory 28 to processor 16.

Bus 18 represents one or more of any of several types of bus structures, including a memory bus or memory controller, a peripheral bus, an accelerated graphics port, and a processor or local bus using any of a variety of bus architectures. By way of example, and not limitation, such architectures include Industry Standard Architecture (ISA) bus, Micro Channel Architecture (MCA) bus, Enhanced ISA (EISA) bus, Video Electronics Standards Association (VESA) local bus, Peripheral Component Interconnect (PCI) bus, Peripheral Component Interconnect Express (PCIe), and Advanced Microcontroller Bus Architecture (AMBA).

Computer system/server 12 typically includes a variety of computer system readable media. Such media may be any available media that is accessible by computer system/server 12, and it includes both volatile and non-volatile media, removable and non-removable media.

System memory 28 can include computer system readable media in the form of volatile memory, such as random access memory (RAM) 30 and/or cache memory 32. Computer system/server 12 may further include other removable/non-removable, volatile/non-volatile computer system storage media. By way of example only, storage system 34 can be provided for reading from and writing to a non-removable, non-volatile magnetic media (not shown and typically called a “hard drive”). Although not shown, a magnetic disk drive for reading from and writing to a removable, non-volatile magnetic disk (e.g., a “floppy disk”), and an optical disk drive for reading from or writing to a removable, non-volatile optical disk such as a CD-ROM, DVD-ROM or other optical media can be provided. In such instances, each can be connected to bus 18 by one or more data media interfaces. As will be further depicted and described below, memory 28 may include at least one program product having a set (e.g., at least one) of program modules that are configured to carry out the functions of embodiments of the disclosure.

Program/utility 40, having a set (at least one) of program modules 42, may be stored in memory 28 by way of example, and not limitation, as well as an operating system, one or more application programs, other program modules, and program data. Each of the operating system, one or more application programs, other program modules, and program data or some combination thereof, may include an implementation of a networking environment. Program modules 42 generally carry out the functions and/or methodologies of embodiments as described herein.

Computer system/server 12 may also communicate with one or more external devices 14 such as a keyboard, a pointing device, a display 24, etc.; one or more devices that enable a user to interact with computer system/server 12; and/or any devices (e.g., network card, modem, etc.) that enable computer system/server 12 to communicate with one or more other computing devices. Such communication can occur via Input/Output (I/O) interfaces 22. Still yet, computer system/server 12 can communicate with one or more networks such as a local area network (LAN), a general wide area network (WAN), and/or a public network (e.g., the Internet) via network adapter 20. As depicted, network adapter 20 communicates with the other components of computer system/server 12 via bus 18. It should be understood that although not shown, other hardware and/or software components could be used in conjunction with computer system/server 12. Examples, include, but are not limited to: microcode, device drivers, redundant processing units, external disk drive arrays, RAID systems, tape drives, and data archival storage systems, etc.

The present disclosure may be embodied as a system, a method, and/or a computer program product. The computer program product may include a computer readable storage medium (or media) having computer readable program instructions thereon for causing a processor to carry out aspects of the present disclosure.

The computer readable storage medium can be a tangible device that can retain and store instructions for use by an instruction execution device. The computer readable storage medium may be, for example, but is not limited to, an electronic storage device, a magnetic storage device, an optical storage device, an electromagnetic storage device, a semiconductor storage device, or any suitable combination of the foregoing. A non-exhaustive list of more specific examples of the computer readable storage medium includes the following: a portable computer diskette, a hard disk, a random access memory (RAM), a read-only memory (ROM), an erasable programmable read-only memory (EPROM or Flash memory), a static random access memory (SRAM), a portable compact disc read-only memory (CD-ROM), a digital versatile disk (DVD), a memory stick, a floppy disk, a mechanically encoded device such as punch-cards or raised structures in a groove having instructions recorded thereon, and any suitable combination of the foregoing. A computer readable storage medium, as used herein, is not to be construed as being transitory signals per se, such as radio waves or other freely propagating electromagnetic waves, electromagnetic waves propagating through a waveguide or other transmission media (e.g., light pulses passing through a fiber-optic cable), or electrical signals transmitted through a wire.

Computer readable program instructions described herein can be downloaded to respective computing/processing devices from a computer readable storage medium or to an external computer or external storage device via a network, for example, the Internet, a local area network, a wide area network and/or a wireless network. The network may comprise copper transmission cables, optical transmission fibers, wireless transmission, routers, firewalls, switches, gateway computers and/or edge servers. A network adapter card or network interface in each computing/processing device receives computer readable program instructions from the network and forwards the computer readable program instructions for storage in a computer readable storage medium within the respective computing/processing device.

Computer readable program instructions for carrying out operations of the present disclosure may be assembler instructions, instruction-set-architecture (ISA) instructions, machine instructions, machine dependent instructions, microcode, firmware instructions, state-setting data, or either source code or object code written in any combination of one or more programming languages, including an object oriented programming language such as Smalltalk, C++ or the like, and conventional procedural programming languages, such as the “C” programming language or similar programming languages. The computer readable program instructions may execute entirely on the user's computer, partly on the user's computer, as a stand-alone software package, partly on the user's computer and partly on a remote computer or entirely on the remote computer or server. In the latter scenario, the remote computer may be connected to the user's computer through any type of network, including a local area network (LAN) or a wide area network (WAN), or the connection may be made to an external computer (for example, through the Internet using an Internet Service Provider). In some embodiments, electronic circuitry including, for example, programmable logic circuitry, field-programmable gate arrays (FPGA), or programmable logic arrays (PLA) may execute the computer readable program instructions by utilizing state information of the computer readable program instructions to personalize the electronic circuitry, in order to perform aspects of the present disclosure.

Aspects of the present disclosure are described herein with reference to flowchart illustrations and/or block diagrams of methods, apparatus (systems), and computer program products according to embodiments of the disclosure. It will be understood that each block of the flowchart illustrations and/or block diagrams, and combinations of blocks in the flowchart illustrations and/or block diagrams, can be implemented by computer readable program instructions.

These computer readable program instructions may be provided to a processor of a general purpose computer, special purpose computer, or other programmable data processing apparatus to produce a machine, such that the instructions, which execute via the processor of the computer or other programmable data processing apparatus, create means for implementing the functions/acts specified in the flowchart and/or block diagram block or blocks. These computer readable program instructions may also be stored in a computer readable storage medium that can direct a computer, a programmable data processing apparatus, and/or other devices to function in a particular manner, such that the computer readable storage medium having instructions stored therein comprises an article of manufacture including instructions which implement aspects of the function/act specified in the flowchart and/or block diagram block or blocks.

The computer readable program instructions may also be loaded onto a computer, other programmable data processing apparatus, or other device to cause a series of operational steps to be performed on the computer, other programmable apparatus or other device to produce a computer implemented process, such that the instructions which execute on the computer, other programmable apparatus, or other device implement the functions/acts specified in the flowchart and/or block diagram block or blocks.

The flowchart and block diagrams in the Figures illustrate the architecture, functionality, and operation of possible implementations of systems, methods, and computer program products according to various embodiments of the present disclosure. In this regard, each block in the flowchart or block diagrams may represent a module, segment, or portion of instructions, which comprises one or more executable instructions for implementing the specified logical function(s). In some alternative implementations, the functions noted in the block may occur out of the order noted in the figures. For example, two blocks shown in succession may, in fact, be executed substantially concurrently, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

The descriptions of the various embodiments of the present disclosure have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein.

What is claimed is:

1. A method of error-corrected communication, the method comprising:
constructing a base matrix comprising a plurality of columns;
applying a plurality of permutations to the base matrix to obtain a plurality of permuted matrices;
generating a parity-check matrix by concatenating the plurality of permuted matrices;
generating a plurality of codewords based on the parity-check matrix;
encoding a message according to the plurality of codewords; and
transmitting the encoded message via a noisy channel.

2. The method of claim 1, further comprising:
receiving the message via the noisy channel; and
decoding the message, said decoding comprising performing error correction of the message based on the parity-check matrix.

3. The method of claim 2, wherein said decoding comprises message-passing decoding.

4. The method of claim 2, wherein said decoding comprises progressive-list decoding.

5. The method of claim 1, wherein each of the plurality of columns has the same Hamming weight.

6. The method of claim 1, wherein the indices of each consecutive pair of non-zero entries in each of the plurality of columns differ by an odd number.

7. The method of claim 1, wherein the plurality of permutations comprises random column-wise permutations.

8. A system comprising:
a network interface coupled to a noisy channel;
a computing node comprising a computer readable storage medium having program instructions embodied therewith, the program instructions executable by a processor of the computing node to cause the processor to perform a method comprising:
constructing a base matrix comprising a plurality of columns;
applying a plurality of permutations to the base matrix to obtain a plurality of permuted matrices;
generating a parity-check matrix by concatenating the plurality of permuted matrices;
generating a plurality of codewords based on the parity-check matrix;
encoding a message according to the plurality of codewords; and
transmitting the encoded message via the noisy channel.

9. The system of claim 8, wherein the processor-executable instructions, when executed by the processor, further cause the processor to:
receive the message via the noisy channel; and
decode the message, said decoding comprising performing error correction of the message based on the parity-check matrix.

10. The system of claim 9, wherein said decoding comprises message-passing decoding.

11. The system of claim 9, wherein said decoding comprises progressive-list decoding.

12. The system of claim 8, wherein each of the plurality of columns has the same Hamming weight.

13. The system of claim 8, wherein the indices of each consecutive pair of non-zero entries in each of the plurality of columns differ by an odd number.

14. The system of claim 8, wherein the plurality of permutations comprises random column-wise permutations.

15. A computer program product for parity-check coding and decoding, the computer program product comprising a computer readable storage medium having program instructions embodied therewith, the program instructions executable by a processor to cause the processor to perform a method comprising:
constructing a base matrix comprising a plurality of columns;
applying a plurality of permutations to the base matrix to obtain a plurality of permuted matrices;
generating a parity-check matrix by concatenating the plurality of permuted matrices;
generating a plurality of codewords based on the parity-check matrix;
encoding a message according to the plurality of codewords; and
transmitting the encoded message via a noisy channel.

16. The computer program product of claim 15, wherein the processor-executable instructions, when executed by the processor, further cause the processor to:
receive the message via the noisy channel; and
decode the message, said decoding comprising performing error correction of the message based on the parity-check matrix.

17. The computer program product of claim 16, wherein said decoding comprises message-passing decoding or progressive-list decoding.

18. The computer program product of claim 15, wherein each of the plurality of columns has the same Hamming weight.

19. The computer program product of claim 15, wherein the indices of each consecutive pair of non-zero entries in each of the plurality of columns differ by an odd number.

20. The computer program product of claim 15, wherein the plurality of permutations comprises random column-wise permutations.
